(19) United States
(12) Patent Application Publication
(10) Pub. No.: US 2004/0261838 A1
(43) Pub. Date: Dec. 30, 2004

(54) Solar cell with an electrically insulating layer under the busbar

(76) Inventors: Hector Cotal, Valencia, CA (US); Dimitri D. Krut, Encino, CA (US); Raed A. Sherif, Valencia, CA (US)

Correspondence Address: MCNEES, WALLACE & NURICK LLC, 100 PINE STREET, P.O. BOX 1166, HARRISBURG, PA, 17108-1166, US

(21) Appl. No.: 10/603,703

(22) Filed: Jun. 25, 2003

(51) Int. Cl. H01L 31/00

(52) U.S. Cl. 136/256; 136/259

(57) ABSTRACT

A solar cell includes a photovoltaic energy source, a frontside array of metallic gridlines deposited upon a front face of the photovoltaic energy source, and a busbar structure in electrical continuity with the frontside array of metallic gridlines. The busbar structure has an electrical insulator layer overlying and contacting the front face of the photovoltaic energy source, and a metallic busbar layer overlying and contacting the electrical insulator layer. The metallic busbar layer is in electrical continuity with the frontside array of metallic gridlines. The solar cell is preferably a concentrator solar cell.

This invention relates to a solar cell protected against current breakdowns and, more particularly, to a concentrator solar cell having a high concentration ratio.

### BACKGROUND OF THE INVENTION

A solar cell comprises two or more layers of photoactive semiconductor material in intimate contact with each other, that forms one or more semiconductor junctions. When stimulated by the proper form of light, such as sunlight, these junctions give rise to electrical energy, which is manifested in the form of a photocurrent and a photovoltage. When an external load is connected across the solar cell, power can be drawn from the circuit by the application of a forward-bias voltage. Advanced solar cells may include more than two semiconductor layers and their respective pairwise semiconductor junctions. The various pairs of semiconductor layers of the advanced solar cells are tuned to the various spectral components of the sun to maximize the power output of the solar cell.

Advanced multilayer solar cells are most advantageously used in concentrator arrangements, wherein the power of the sun over an area larger than the surface area of the solar cell is concentrated onto the solar cell by mirrors or otherwise. Each concentrator solar cell produces a significantly higher current output than each non-concentrator solar cell with the same surface area. The concentrator solar cell is more expensive to produce but its cost may be offset with operation at high concentration levels. The determination of whether to use a concentrator solar cell or a non-concentrator solar cell depends upon the application of the solar cell, but many terrestrial solar cells would use concentrator solar cells for electric power utilities, for example, if they could be made to work at low cell and system costs and high concentration ratios. Likewise, many space applications would benefit from concentrator solar cells if they could be made lightweight and compact. The concentration ratio is typically expressed in multiples of 1 sun intensity, for example 200 suns, meaning that the intensity of solar energy incident upon the front face of the solar cell is 200 times the normal intensity of the sun over that same surface area.

The current produced as a result of the absorption of light in the semiconductor layers is collected by a collector structure having metallic gridlines deposited upon the front face of the solar cell facing the sun, and a backside metallic electrode on the back face of the solar cell away from the sun. The collected current is then conducted away from the collector structure by a busbar structure. The busbar structure is deposited upon the front face of the solar cell, usually along its edges. This structure works well for non-concentrator solar cells.

However, this structure is limited in its ability to function properly in the higher-current conditions of concentrator solar cells at the higher concentration ratios, particularly above about 200 suns. High current is also dependent upon the size of the solar cell active area. Existing designs fail prematurely, so that any attempts to reduce solar cell and system costs as compared to typical solar cells are negated by its reduced operation lifetime. Particularly for solar cells used in relatively inaccessible locations, such as those on high-concentration systems, the reduced lifetimes rule them out as candidates.

There is accordingly a need for a solar cell that is suitable for use as a high-concentration-ratio concentrator solar cell, or for lower-concentration-ratio or even non-concentrator solar cells. The present invention fulfills this need, and further provides related advantages.

### SUMMARY OF THE INVENTION

The present invention provides a solar cell which has improved current-carrying characteristics as compared with prior solar cells. The present approach achieves its greatest benefits when applied to concentrator solar cells, where the electrical currents from the gridlines are sent to and conducted by the busbar structure, so that the electrical currents in the busbar structure are high. By carrying higher electrical currents in the busbar structure, the concentrator solar cell can operate to higher concentration ratios and thence higher efficiencies than conventional concentrator solar cells. The lifetime of the solar cell is enhanced by extending the failure threshold of the solar cell. Higher open-circuit voltages are produced than in non-concentrator solar cells, thereby permitting high fill factors. Additionally, and as an added benefit, the reverse bias breakdown voltage is increased while decreasing the device saturation current.

In accordance with the invention, a solar cell comprises a photovoltaic energy source, including contacting n-type and p-type semiconductor layers, having a front face and an oppositely disposed back face. The solar cell has a frontside array of metallic gridlines deposited upon the front face of the photovoltaic energy source. There is also typically a backside metallic electrode overlying and contacting the back face of the photovoltaic energy source. A busbar structure is in electrical continuity with the frontside array of metallic gridlines. The busbar structure comprises an electrical insulator layer overlying and contacting the front face of the photovoltaic energy source, and a metallic busbar layer overlying and contacting the electrical insulator layer. The metallic busbar layer is in electrical continuity with the frontside array of metal gridlines.

The photovoltaic energy source may be of any operable type. Typically, it is a relatively thin planar structure with two or more layers of semiconductor material, in one preferred case grown by Metal Organic Vapor Phase Epitaxy (MOVPE) from the elemental groups of III-V elements in the periodic table. The simplest photovoltaic energy sources have exactly two layers of photoactive semiconductor material, while the more complex, higher-current photovoltaic energy sources that are used in concentrator solar cells have more than two layers of photoactive semiconductor material.

The electrical insulator layer of the busbar structure is preferably an oxide such as silicon dioxide (SiO₂). The electrical insulator layer has a preferred thickness of from about 0.3 to about 2 micrometers, most preferably with an optimum thickness of about 0.5 micrometers. It is also preferred that the electrical insulator layer extends laterally from underneath the metallic busbar layer so that it overlaps (i.e., is wider than) the metallic busbar layer, to avoid edge current leakages between the metallic busbar layer and the photovoltaic energy source.

As noted, the present approach achieves its greatest benefits when the solar cell is a concentrator solar cell including a solar concentrator disposed to concentrate solar energy toward the front face of the photovoltaic energy source. Preferably, the solar concentrator produces a concentration ratio of more than 200 suns, most preferably from about 300 to about 500 suns, and as much as 1000 suns or more.

It has been determined that the cause of the current limitation and premature failure of conventional concentrator solar cells having a high concentration ratio is a result of the heat produced by tiny local current shunts (sometimes termed “filaments”) that short the metallic busbar layer through the underlying semiconductor material of the photovoltaic energy source. These current shunts result from minute semiconductor imperfections and particles of foreign matter in the semiconductor material as a result of the growth process. It may be possible to avoid such imperfections and particles consistently by modifying the crystal growth techniques, but no such solutions are currently available.

Instead, the present approach places the electrical insulator layer between the metallic busbar layer and the surface of the semiconductor material of the photovoltaic energy source. The electrical insulator layer prevents current flow through the shunts, avoiding the local heating that is the predominant failure mechanism. This approach is somewhat counterintuitive, inasmuch as it reduces the amount of metallic conductor serving as the frontside electrical contact with the photovoltaic energy source, thereby apparently resulting in increased current density in the array of metallic gridlines. However, this is not the case because the solar cell grid pattern is designed to compensate for the lack of current collection in the semiconductor material just underneath the isolated metallic busbar layer. It has been found that the avoiding of the shunt-failure mechanism allows significantly higher currents to flow through the metallic busbar layer that conducts electrical current from the frontside array of metallic gridlines.

The present approach does not place any electrical insulation layer under the array of metallic gridlines, because this would adversely affect their current collection from the front face of the solar cell.

The present approach therefore allows the solar cell to operate to higher currents, and with better electrical properties, than conventional solar cells. Other features and advantages of the present invention will be apparent from the following more detailed description of the preferred embodiment, taken in conjunction with the accompanying drawings, which illustrate, by way of example, the principles of the invention. The scope of the invention is not, however, limited to this preferred embodiment.

### BRIEF DESCRIPTION OF THE DRAWINGS

FIG. 1 is a schematic elevational view of a concentrator solar cell;

FIG. 2 is a planar view of a solar cell shown in FIG. 1;

FIG. 3 is a perspective view of the solar cell of FIG. 2

FIG. 4 is a sectional view of the solar cell of FIG. 2, taken along line 4-4 of FIG. 2; and

FIG. 5 is a block flow diagram of an approach for preparing the solar cell.

### DETAILED DESCRIPTION OF THE INVENTION

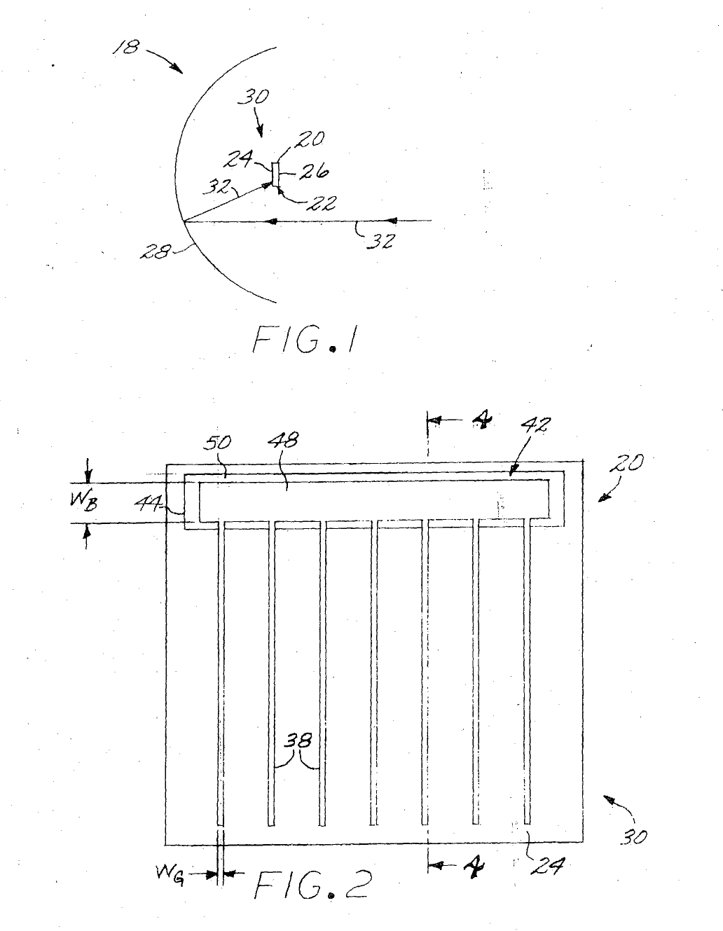

FIG. 1 depicts a solar cell 20 that includes a voltage/current-producing element 30 having a solar cell 20 including a photovoltaic energy source 22 with a front face 24 and an oppositely disposed back face 26. In the illustrated case, the solar cell 20 is part of a concentrator solar cell 18 having a solar concentrator 28 disposed to concentrate solar energy toward the front face 24 of the photovoltaic energy source 22 The solar concentrator 28 may include a mirror, a refractive lens, or a combination of mirrors and lenses. The depicted solar concentrator 28 is a parabolic mirror with the solar cell 20 located near the parabolic focus, although other forms of solar concentrators 28 may be used. A depicted ray path 32 shows the path of sunlight reflected from the solar concentrator 28 to the voltage/current-producing element 30.

While the present approach is useful with all solar cells, it is most beneficially applied with such a concentrator solar cell 18 with a concentration ratio of more than 200 suns, most preferably from about 300 to about 500 suns. (The concentration ratio is expressed in multiples of 1 sun intensity. A concentration ratio of 200 indicates that the intensity of the solar radiation incident upon the front face 24 of the photovoltaic energy source 22 is 200 times the usual intensity of the sun over that same surface area.)

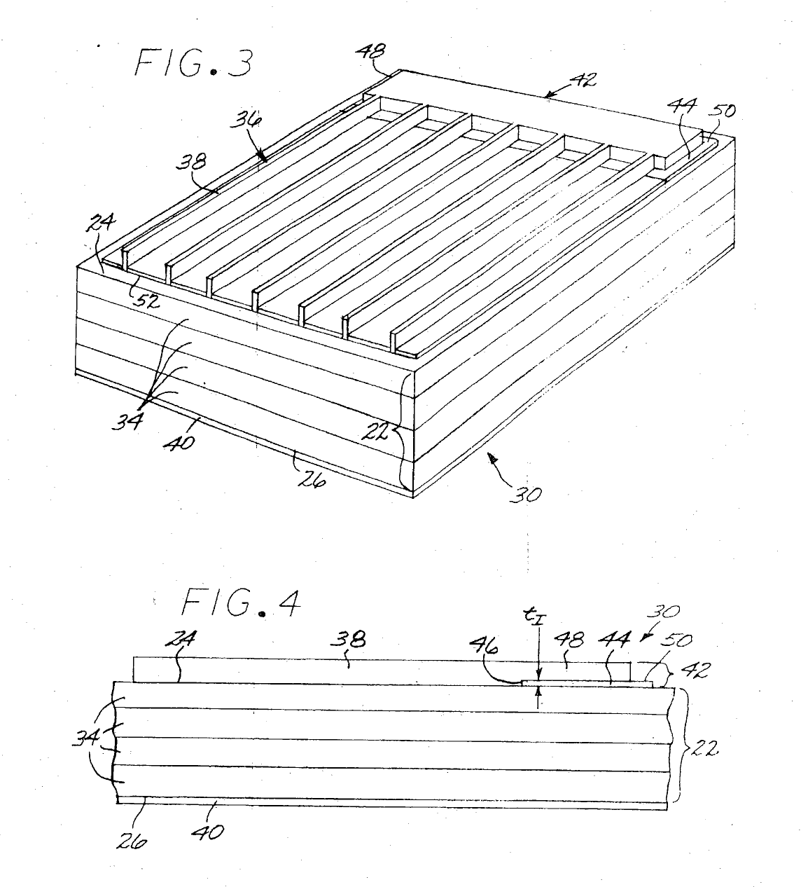

FIGS. 2-4 illustrate the voltage/current-producing element 30 in greater detail and in various views. The photovoltaic energy source 22 is a relatively thin, multilayer structure of semiconductor layers 34, each formed of a semiconductor material, in facing contact with each other and selected to produce a voltage therebetween when illuminated by sunlight or other light. The photovoltaic energy source 22 may have exactly two semiconductor layers 34, or it may have more than two semiconductor layers 34. Photovoltaic energy sources 22 having more than two semiconductor layers 34, and often as many as 200 semiconductor layers 34 or more, are preferably used in concentrator solar cells 18. The structure of such photovoltaic energy sources 22 and their fabrication techniques, except for the features discussed herein, are known in the art, see for example U.S. Pat. No. 5,330,585, whose disclosure is incorporated by reference.

The voltage/current-producing element 30 of the solar cell 20 further includes a current collector structure 36 including a frontside array of metallic gridlines 38 deposited upon the front face 24 of the photovoltaic energy source 22. The light reaches the photovoltaic energy source 22 through the gaps between the metallic gridlines 38. The current collector structure 36 also includes a backside metallic electrode 40 overlying and contacting the back face 26 of the photovoltaic energy source 22. The backside metallic electrode 40 typically covers the entire back face 26 of the photovoltaic energy source 22, as there is no need to illuminate the back face 26 of the photovoltaic energy source 22. The metallic gridlines 38 have a narrowest width W_{G}, measured in the plane of the photovoltaic energy source 32, that is typically about 15 micrometers. The metallic gridlines 38 are typically about 5 micrometers thick, and the backside metallic electrode 40 is typically about 5 micrometers thick. The metallic gridlines 38 and the backside metallic electrode 40 collect the electrical current produced when a forward-bias voltage is applied across the semiconductor photovoltaic energy source 22. The metallic gridlines 38 and the backside metallic electrode 40 are each metals, typically silver.

A busbar structure 42 provides electrical continuity with the frontside array of metallic gridlines 38. The busbar structure 42 conducts electrical current collected from the front face 24 of the photovoltaic energy source 22 by the metallic gridlines 38, to external locations (not shown).

The busbar structure 42 comprises an electrical insulator layer 44 overlying and contacting a portion of the front face 24 of the photovoltaic energy source 22. The electrical insulator layer 44 is preferably an oxide or a nitride, most preferably silicon dioxide (SiO₂). The electrical insulator layer 44 preferably has a thickness t₁ of from about 0.3 to about 2 micrometers, most preferably about 0.5 micrometers. If the thickness t₁ of the electrical insulator layer 44 is less than about 0.3 micrometers, there is a risk from the emergence of bare spots where no electrical insulator layer 44 is deposited, or of pinholes through the electrical insulator layer 44. In either case, the result is that there may be an additional current concentration at any potential shunt locations. If the thickness t₁ of the electrical insulator layer 44 is more than about 2 micrometers, there is a possibility that the built-in strain between the insulator layer 44 and the semiconductor layers 34 of the photovoltaic energy source 22 will relax, compromising the integrity of the insulator layer 44. This effect works in concert with the thermal stresses resulting from thermal strains due to differences in coefficients of thermal expansion that may cause the electrical insulator layer 44 to delaminate from the photovoltaic energy source 22 and fail. Additionally, an electrical insulator layer 44 that is too thick produces too high a step 46 between the metallic gridlines 38 and the metallic busbar layer that can pinch the flow of electrical current from the metallic gridlines 38 to the metallic busbar layer.

The busbar structure 42 further includes a metallic busbar layer 48 overlying and contacting the electrical insulator layer 44. The metallic busbar layer 48 is in electrical continuity with the frontside array of metal gridlines 38. The metallic busbar layer 48 has a narrowest width W_{B}, measured in the plane of the photovoltaic energy source 32, that is much larger than W_{G}. The metallic busbar layer 48 is made of metal, usually the same metal as the metallic gridlines 38, and is typically about 5 micrometers thick.

The electrical insulator layer 44 prevents the formation of current shunts between the metallic busbar layer 48 and imperfections and foreign matter that may lie in the photovoltaic energy source 22 at its front face 24, as a result of the crystal growth or deposition processes by which the metallic busbar layer 44 and the photovoltaic energy source 22 were produced. Desirably, the electrical insulator layer 44 extends laterally beyond the metallic busbar layer 48 to form an overlap 50. That is, the electrical insulator layer 44 is preferably wider than the metallic busbar layer 48 in all directions in the plane of the front face 24. The overlap 50 prevents any current paths and thence shorting between the metallic busbar layer 48 and the photovoltaic energy source 22.

The remaining portion of the front face 24 of the photovoltaic energy source 22, not covered by the metallic gridlines 38 and the busbar structure 42, is optionally covered with a conventional multilayer antireflective coating 52.

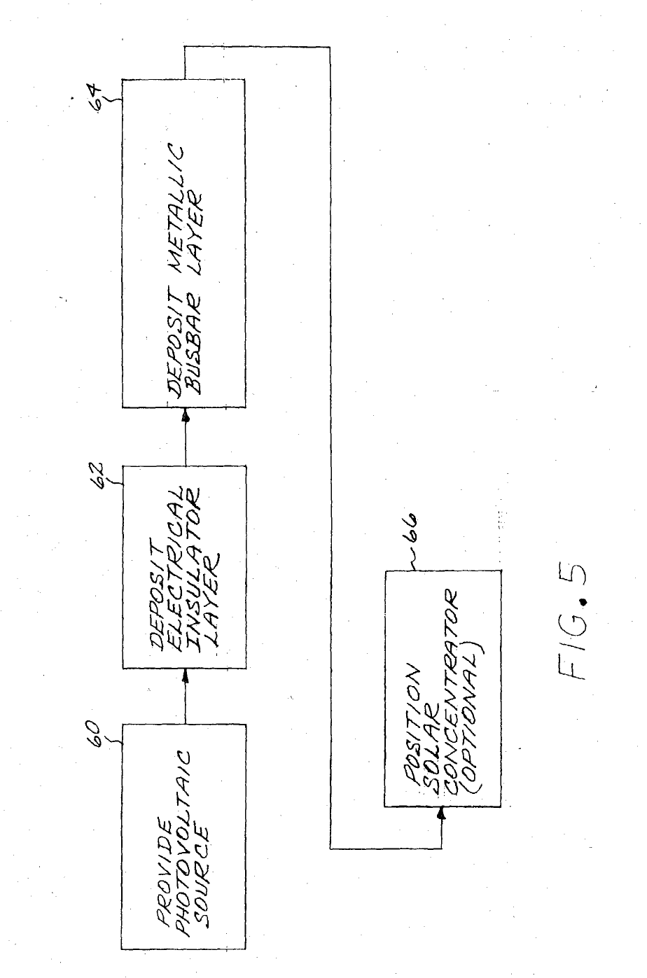

FIG. 5 depicts an approach for fabricating the solar cell 20. The photovoltaic energy source 22 is produced and provided, step 60. Techniques for producing photovoltaic energy sources 22 are known in the art and are described, for example, in U.S. Pat. No. 5,330,585.

The electrical insulator layer 44 is deposited, step 62, using an appropriate mask to define its extent. In the case where the electrical insulator layer 44 is silicon dioxide, the electrical insulator layer 44 is preferably deposited by low-pressure chemical vapor deposition (LPCVD) or plasma-enhanced chemical vapor deposition (PECVD).

The metallic busbar layer 48 is deposited, step 64, using appropriate photo-masks as necessary to define its lateral extent (which is preferably less than the lateral extent of the electrical insulator layer 44, leaving the overlap 50). In the case of the silver metallic busbar layer 48, the deposition step 64 is preferably accomplished by physical vapor deposition.

Where used, the solar concentrator 28 is positioned relative to the voltage/current-producing element 30, step 66, to complete the fabrication of the concentrator solar cell 18.

Concentrator solar cells according to the present approach and designed for concentration ratios of 325 suns have been fabricated and comparatively tested with concentrator solar cells of the same configuration but without the electrical insulator layer 44. The concentrator solar cells which have the electrical insulator layer 44 fail at an average of about 5.6 amperes average forward-bias current, while the concentrator solar cells which do not have the electrical insulator layer 44 fail at about 3.5 amperes average forward-bias current. This important result means that the concentrator solar cells which do have the electrical insulator layer 44 can operate at concentration ratios of up to about 350 suns, while the concentrator solar cells which do not have the electrical insulator layer 44 can operate at a maximum concentration ratio of only about 200 suns, for this particular design. For other solar cell designs that can function with higher electrical currents, the concentration ratio reaches a higher threshold for continuous operation than what has been just described. In particular, concentrator solar cells fabricated for 500 and 1000 suns have been designed with the present approach and have succeeded in their operation without failure.

The concentrator solar cells with and without the electrical insulator layer 44 were also tested in reverse bias conditions. The presence of the electrical insulator layer 44 resulted in increased reverse-bias breakdown voltages and lower saturation currents.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A solar cell comprising:
a photovoltaic energy source having a front face and an oppositely disposed back face;
a frontside array of metallic gridlines deposited upon the front face of the photovoltaic energy source; and
a busbar structure in electrical continuity with the frontside array of metallic gridlines, the busbar structure comprising
an electrical insulator layer overlying and contacting the front face of the photovoltaic energy source, and
a metallic busbar layer overlying and contacting the electrical insulator layer, wherein the metallic busbar layer is in electrical continuity with the frontside array of metallic gridlines.

2. The solar cell of claim 1, wherein the photovoltaic energy source comprises exactly two layers of semiconductor material.

3. The solar cell of claim 1, wherein the photovoltaic energy source comprises more than two layers of semiconductor material.

4. The solar cell of claim 1, wherein the solar cell further includes
a backside metallic electrode overlying and contacting the back face of the photovoltaic energy source.

5. The solar cell of claim 1, wherein the electrical insulator layer is an oxide or a nitride.

6. The solar cell of claim 1, wherein the electrical insulator layer has a thickness of from about 0.3 to about 2 micrometers.

7. The solar cell of claim 1, wherein the electrical insulator layer has a thickness of about 0.5 micrometers.

8. The solar cell of claim 1, wherein the electrical insulator layer extends laterally beyond the metallic busbar layer.

9. The solar cell of claim 1, further including
a solar concentrator disposed to concentrate solar energy toward the front face of the photovoltaic energy source.

10. The solar cell of claim 1, further including
a solar concentrator disposed to concentrate solar energy toward the front face of the photovoltaic energy source with a concentration ratio of more than 200 suns.

11. The solar cell of claim 1, further including
a solar concentrator disposed to concentrate solar energy toward the front face of the photovoltaic energy source with a concentration ratio of from about 300 to about 500 suns.

12. A solar cell comprising:
a photovoltaic energy source comprising at least two layers of semiconductor material and having a front face and an oppositely disposed back face;
a solar concentrator disposed to concentrate solar energy toward the front face of the photovoltaic energy source;
a frontside array of metallic gridlines deposited upon the front face of the photovoltaic energy source;
a backside metallic electrode overlying and contacting the back face of the photovoltaic energy source;
a busbar structure in electrical continuity with the frontside array of metallic gridlines, the busbar structure comprising
an electrical insulator layer overlying and contacting the front face of the photovoltaic energy source, and
a metallic busbar layer overlying and contacting the electrical insulator layer, the metallic busbar layer being in electrical continuity with the frontside array of metallic gridlines.

13. The solar cell of claim 12, wherein the electrical insulator layer is an oxide.

14. The solar cell of claim 12, wherein the electrical insulator layer has a thickness of from about 0.3 to about 2 micrometers.

15. The solar cell of claim 12, wherein the electrical insulator layer has a thickness of about 0.5 micrometers.

16. The solar cell of claim 12, wherein the electrical insulator layer extends laterally beyond the metallic busbar layer.

17. The solar cell of claim 12, wherein
the solar concentrator has a concentration ratio of from about 300 to about 500 suns.
